(19) United States
(12) Patent Application Publication
(10) Pub. No.: US 2011/0169501 A1
(43) Pub. Date: Jul. 14, 2011

(54) DELAY CIRCUIT

(75) Inventor: Naoki Sato, Tokyo (JP)

(73) Assignee: ADVANTEST CORPORATION, Tokyo (JP)

(21) Appl. No.: 13/120,423

(22) PCT Filed: Sep. 24, 2008
(86) PCT No.: PCT/JP2008/002644

§ 371 Date: Mar. 22, 2011

(51) Int. Cl. H01H 31/02; H03L 7/06

(52) U.S. Cl. 324/555; 327/158

(57) ABSTRACT

A sub-delay element has the same configuration as that of a main delay element, and applies a delay τ that corresponds to a bias voltage to a selected clock signal output from a first selector. A phase detectorgenerates a phase detection signal that corresponds to the phase difference between a selected clock signal that has propagated through the sub-delay element and a selected clock signal that has propagated through a bypass path. A counter performs a count operation according to the phase detection signal. A D/A converter supplies a bias voltage that corresponds to the count value of the counter to the main delay element and the sub-delay element. An initialization unit instructs a DLL circuit to actually operate, and sets the reference voltage to be supplied to the D/A converter based upon the fluctuation in the count value of the counter.

### CROSS REFERENCE TO RELATED APPLICATION

This application is the U.S. National Stage of International Patent Application No. PCT/JP2008/002644 filed on Sep. 24, 2008 and claims priority thereto, the disclosure of which is hereby incorporated by reference in its entirety.

### BACKGROUND OF THE INVENTION

1. Field of the Invention

The present invention relates to a delay circuit, and particularly to a technique for stabilizing the delay amount by a feedback operation.

2. Description of the Related Art

An automatic test apparatus (Automatic Test Equipment, which will be referred to as the “ATE” hereafter) configured to test a semiconductor device mounts a timing generator configured to control the timing of a test pattern to be supplied to a device under test (which will be referred to as the “DUT” hereafter). The timing generator is capable of setting the edge timing of each data in increments of cycles of the test pattern.

The edge timing adjustment is executed in two stages, i.e., in a logic unit and a high-precision adjustment unit. The logic unit shifts the edge timing in units of the period of the operation clock of a tester. The high-precision adjustment unit adjusts the delay amount with a higher resolution than that of the period of the clock signal supplied to the logic unit. For example, the high-precision adjustment circuit delays a pulse edge in two stages, i.e., using a coarse delay and a fine delay. A delay circuit configured to apply such a coarse delay employs a method in which gate delay elements each configured to apply a unit delay amount are cascade-connected, and the number of stages thus cascaded-connected is switched so as to control the delay amount.

The delay amount of each gate delay element changes due to the temperature and the power supply voltage. In order to suppress fluctuation in the delay amount, a technique has been proposed in which the delay amount of each gate delay element is stabilized using the DLL (Delay Locked Loop) method or the PLL (Phase Locked loop) method.

### SUMMARY OF THE INVENTION

The present invention has been made in view of such a situation. Accordingly, it is an overall purpose of the present invention to provide a delay circuit which allows high-precision calibration.

An embodiment of the present invention relates to a delay circuit configured to apply a delay to an input signal. The delay circuit comprises: a main delay element configured to apply a delay that corresponds to a bias voltage to the input signal; a first selector configured to receive a reference clock signal and a loop clock signal, and to select one signal from among these two signals thus received; a sub-delay element having the same configuration as that of the main delay element, and configured to apply a delay that corresponds to the bias voltage to a selected clock signal output from the first selector; a bypass path configured to bypass the sub-delay element; a phase detector configured to detect the phase difference between the selected clock signal that has propagated through the sub-delay element and the selected clock signal that has propagated through the bypass path, and to generate a phase detection signal having a level that corresponds to the phase difference thus detected; a counter configured to perform a counting operation according to the level of the phase detection signal received from the phase detector; a D/A converter configured to convert the count value of the counter into an analog voltage, and to supply the analog voltage thus converted as the bias voltage to the main delay element and the sub-delay element; a bias circuit configured to generate a reference voltage to be supplied to the D/A converter; and a loop oscillator comprising a second selector configured to receive the selected clock signal that has propagated through the sub-delay element and the selected clock signal that has propagated through the bypass path, to select one from among the clock signals thus received, and to supply the clock signal thus selected as the loop clock signal to the first selector, and configured to operate as an oscillator in a state in which the first selector selects the loop clock signal.

With such an embodiment, when the first selector selects a reference clock, a DLL (Delay Locked Loop) is formed, thereby stabilizing the delay amount of the delay circuit such that it matches the period of the reference clock. Furthermore, by joining together the states of the first selector and the second selector, such an arrangement provides execution of a calibration operation in a flexible manner. Thus, such an arrangement provides high-precision calibration of the delay circuit.

Also, a delay circuit according to an embodiment may further comprise an initialization unit configured to instruct the delay circuit to operate, to monitor the count value of the counter, and to set the reference voltage such that fluctuation in the count value is within a predetermined range, in a state in which the first selector selects the reference clock signal.

By monitoring the count value in a state in which the delay circuit is actually operated, and by setting the reference voltage based upon fluctuation in the count value thus monitored, such an arrangement ensures a required tracking margin.

Also, in the calibration operation, the initialization unit may instruct the delay circuit to operate for a predetermined period of time in a state in which the first selector selects the reference clock signal, and may set the reference voltage so as to prevent overflow or underflow of the count value of the counter.

Also, a delay circuit according to an embodiment may further comprise a period measurement unit configured to measure a period of the loop oscillator. Also, the initialization unit may set at least one from among the reference voltage and the initial value of the counter based upon the period measured by the period measurement unit.

With such an embodiment, by initializing the delay circuit based upon the period of the loop oscillator, such an arrangement provides higher-precision calibration.

Also, the initialization unit may perform coarse adjustment of at least one from among the reference voltage and the initial value of the counter, based upon the period before the setting of the reference voltage based upon the fluctuation in the count value.

Also, the initialization unit may execute the following processing.

1. Acquisition of a first period of the loop oscillator, measured by the period measurement unit in a state in which the first selector selects the loop clock signal, the second selector selects the selected clock signal that has propagated through the bypass path, and the counter is fixed to an initial value.

2. Acquisition of a second period of the loop oscillator, measured by the period measurement unit in a state in which the first selector selects the loop clock signal, the second selector selects the selected clock signal that has propagated through the sub-delay element, and the counter is fixed to the initial value.

3. Setting of at least one from among the reference voltage and the initial value such that the difference between the second period and the first period is within a predetermined range.

The difference between the first period and the second period represents the net delay amount due to the sub-delay element. Thus, by initializing the delay circuit based upon this difference, such an arrangement provides higher-precision calibration.

Also, the predetermined range used in the step for determining the difference between the periods may include a period of the reference clock signal.

In the initialized state, such an arrangement allows the delay amount of the sub-delay element to approach the period of the reference clock signal.

Also, the initialization unit may execute the following processing.

1. Acquisition of a third period of the loop oscillator measured by the period measurement unit in a state in which the first selector selects the loop clock signal, the second selector selects the selected clock signal that has propagated through the sub-delay element, and the counter is fixed to a first count value.

2. Acquisition of a fourth period of the loop oscillator measured by the period measurement unit in a state in which the first selector selects the loop clock signal, the second selector selects the selected clock signal that has propagated through the sub-delay element, and the counter is fixed to a second count value.

3. Acquisition of a resolution by dividing the difference between the third period and the fourth period by the difference between the first count value and the second count value.

4. Setting of the reference voltage such that the resolution thus acquired is within a predetermined range.

The resolution thus obtained can be used as a parameter in setting the loop gain of the DLL circuit. Thus, by performing such an operation, such an arrangement provides optimization of the loop gain.

Also, the initialization unit may perform coarse adjustment of the reference voltage based upon the resolution before the reference voltage is set according to the fluctuation in the count value.

Another embodiment of the present invention relates to a timing generator to be mounted on a test apparatus configured to supply a test pattern to a device under test. The timing generator comprises a delay circuit according to any one of the above-described embodiments, configured to apply a predetermined delay to a signal used to set an edge timing of the test pattern.

Yet another embodiment of the present invention relates to a test apparatus configured to supply a test pattern to a device under test. The test apparatus comprises: a pattern generator configured to generate a test pattern; and the aforementioned timing generator, configured to be capable of changing the edge timing of the test pattern as desired.

It is to be noted that any arbitrary combination or rearrangement of the above-described structural components and so forth is effective as and encompassed by the present embodiments.

Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a circuit diagram which shows a configuration of a delay circuit according to an embodiment;

FIG. 2 is a diagram which shows the relation between the reference voltage Vref and the count value COUNT when the delay circuit shown in FIG. 1 actually operates;

FIG. 3 is a flowchart which shows a calibration operation obtained by combining a first calibration operation through a third calibration operation;

FIG. 4 is a block diagram which shows a configuration of a timing generator employing the delay circuit shown in FIG. 1 and a test apparatus; and

FIG. 5 is a circuit diagram which shows a configuration of a delay circuit according to a modification.

### DETAILED DESCRIPTION OF THE INVENTION

Description will be made below regarding preferred embodiments according to the present invention with reference to the drawings. The same or similar components, members, and processes are denoted by the same reference numerals, and redundant description thereof will be omitted as appropriate. The embodiments have been described for exemplary purposes only, and are by no means intended to restrict the present invention. Also, it is not necessarily essential for the present invention that all the features or a combination thereof be provided as described in the embodiments.

In the present specification, a state represented by the phrase “the member A is connected to the member B” includes a state in which the member A is indirectly connected to the member B via another member that does not affect the electric connection therebetween, in addition to a state in which the member A is physically and directly connected to the member B.

Similarly, a state represented by the phrase “the member C is provided between the member A and the member B” includes a state in which the member A is indirectly connected to the member C, or the member B is indirectly connected to the member C via another member that does not affect the electric connection therebetween, in addition to a state in which the member A is directly connected to the member C, or the member B is directly connected to the member C.

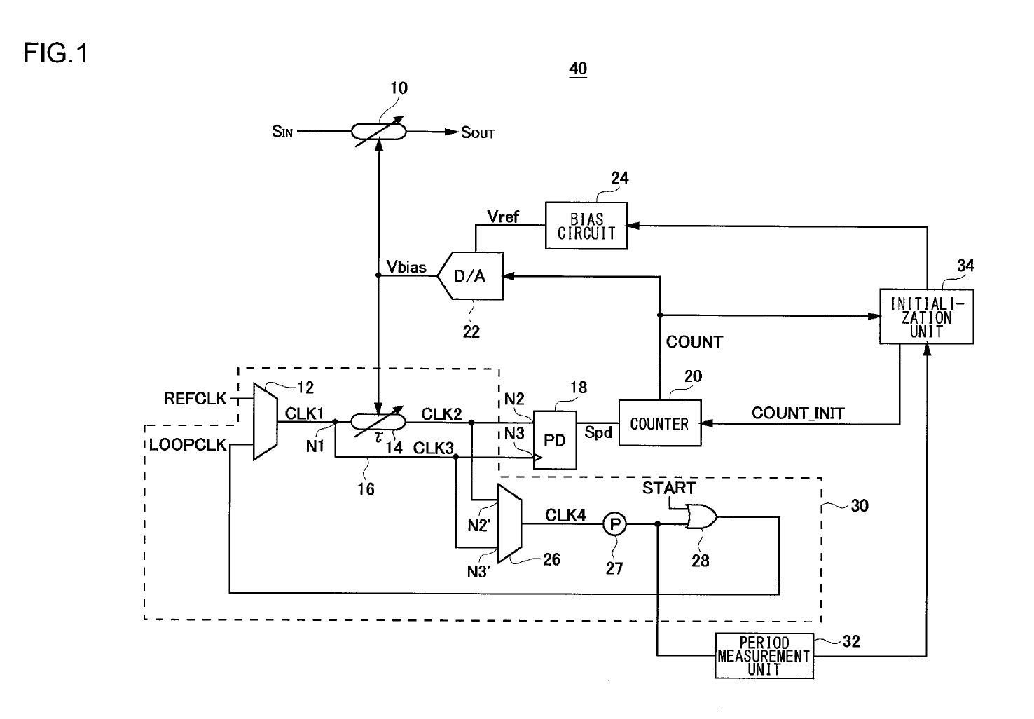

FIG. 1 is a circuit diagram which shows a configuration of a delay circuit 40 according to an embodiment. The delay circuit 40 applies a predetermined delay to an input signal S_{IN}, and outputs the signal thus delayed as an output signal S_{OUT}.

The delay circuit 40 includes a main delay element 10, a first selector 12, a sub-delay element 14, a bypass path 16, a phase detector 18, a counter 20, a D/A converter 22, a bias circuit 24, a second selector 26, a loop oscillator 30, a period measurement unit 32, and an initialization unit 34.

The main delay element 10 applies a delay to the input signal S_{IN}. The delay amount applied by the main delay element 10 changes according to the bias voltage Vbias. For example, the main delay element 10 has a configuration including an inverter or a buffer configured to operate using the bias voltage Vbias as the power supply voltage. Alternatively, an arrangement may be made in which the bias current supplied to such an inverter or a buffer configured as the main delay element changes according to the bias voltage Vbias. The configuration of the main delay element 10 may be made as desired, and is not restricted in particular. With such an arrangement employing an inverter or a buffer, as the bias voltage Vbias (bias current) is increased, the delay amount is reduced, and as the bias voltage Vbias is reduced, the delay amount is increased.

The first selector 12 receives a reference clock signal REFCLK and a loop clock signal LOOPCLK, and outputs one of the signals thus received.

The sub-delay element 14 has the same configuration as that of the main delay element 10, and operates receiving the same bias voltage Vbias as that used by the main delay element 10. The main delay element 10 according to the embodiment adjusts the bias voltage Vbias by a feedback operation such that the delay amount τ applied by the sub-delay element 14 approaches a target value Tp. That is to say, the sub-delay element 14 is arranged in order to monitor the delay amount applied by the main delay element 10.

The sub-delay element 14 applies a delay that corresponds to the bias voltage Vbias to a selected clock signal CLK output from the first selector 12.

The bypass path 16 is arranged in parallel with the sub-delay element 14, and is configured to bypass the sub-delay element 14. The selected clock signal CLK1 output from the first selector 12 is supplied to a downstream circuit via the sub-delay element 14 or via the bypass path 16.

The phase detector 18 detects the phase difference between the selected clock signal CLK2 that passes through the sub-delay element 14 and the selected clock signal CLK3 that passes through the bypass path 16, and generates a phase detection signal Spd having a level that corresponds to the phase difference. For example, when the selected clock signal CLK2 is running ahead of the selected clock signal CLK3, the phase detection signal Spd is set to a first level (e.g., high level), and when the selected clock signal CLK2 is running behind the selected clock signal CLK3, the phase detection signal Spd is set to a second level (low level) that is complementary to the first level. It should be noted that the assignment of the high level and the low level is shown for exemplary purposes only, and is no more than a matter of design choice.

The counter 20 performs a count operation according to the level of the phase detection signal Spd received from the phase detector 18. When the phase detection signal Spd is the first level (when the selected clock signal CLK1 is running ahead), a counting-down count operation is performed. When the phase detection signal Spd is the second level, a counting-up count operation is performed.

The D/A converter 22 converts the count value COUNT of the counter 20 into an analog voltage. The D/A converter 22 supplies the output thereof as the bias voltage Vbias to the main delay element 10 and the sub-delay element 14. The configuration and type of the D/A converter 22 are not restricted in particular. The D/A converter 22 may be configured using various kinds of known circuits.

The bias circuit 24 generates a reference voltage Vref for the D/A converter 22. The dynamic range and the resolution of the bias circuit 24 are set according to the reference voltage Vref.

The loop oscillator 30 includes the second selector 26. The second selector 26 receives the selected clock signal CLK2 that passes through the sub-delay element 14 and the selected clock signal CLK3 that passes through the bypass path 16, and selects one of the signals thus received. The clock signal CLK4 output from the second selector 26 is supplied as the loop clock signal LOOPCLK to the first selector 12 via a pulser 27 and an OR gate 28.

The loop oscillator 30 operates as an oscillator when the first selector 12 selects the loop clock signal LOOPCLK. The pulser 27 generates a pulse that corresponds to the input clock signal CLK4. The OR gate 28 outputs the logical OR of the input signal and a start signal START received from an external circuit. When the level of the start signal START is changed, a trigger is injected into the loop oscillator 30, whereby the loop oscillator 30 starts to oscillate. It should be noted the presence or absence and the layout of the pulser 27 and the OR gate 28 are no more than a matter of design choice.

The period measurement unit 32 measures the period Tpd provided by the loop oscillator 30.

The initialization unit 34 executes calibration processing so as to initialize the delay circuit 40. In the calibration step, the initialization unit 34 sets the reference voltage Vref to be generated by the bias circuit 24, and sets the initial value of the counter 20.

The above is the configuration of the delay circuit 40. Next, description will be made regarding the operation thereof.

When the first selector 12 selects the reference clock REFCLK in the actual operation of the delay circuit 40, a DLL circuit composed of the sub-delay element 14, the phase detector 18, the counter 20, and the D/A converter 22, is set to the active state. The delay amount t of the sub-delay element 14 is stabilized by the feedback operation such that the edge timings of the clock signals CLK2 and CLK3 input to the phase detector 18 match each other.

Description will be made below with Tp as the period of the reference clock signal REFCLK, with TpdA as the period of time required for the selected clock signal CLK1 to propagate through the bypass path 16 from the node N1 to the node N3, and with (TpdB+τ) as the period of time required for the selected clock signal CLK1 to propagate through a path including the sub-delay element 14 from the node N1 to the node N2. The symbol τ represents the delay amount of the sub-delay element 14, and TpdB represents the propagation time required for a signal to propagate through the line from the node N1 to the node N2 excluding for the sub-delay element 14.

The phase detector 18 compares the timing of a given edge of the clock signal CLK2 after it has propagated through the path including the sub-delay element 14 and the timing of the next-cycle edge of the clock signal CLK3 after it has propagated through the bypass path 16. Thus, in the DLL circuit, the delay time τ is adjusted so as to satisfy the relation (TpdB+τ)=TpdA+Tp. In a case in which the circuit is designed such that the relation TpdA=TpdB is satisfied, the delay amount τ of the sub-delay element 14 matches the period Tp of the reference clock signal REFCLK.

A common bias voltage Vbias is supplied to the sub-delay element 14 and the main delay element 10. Thus, the delay amount of the main delay element 10 can be maintained at a constant level.

Before the actual operation, the initialization unit 34 executes a calibration operation. The calibration operation is executed by executing a combination of desired operations made by selection from among the following first through third calibration operations, or by executing a particular single calibration operation.

1. First Calibration Operation

When the first selector 12 selects the reference clock signal REFCLK, the DLL circuit composed of the sub-delay element 14, the phase detector 18, the counter 20, and the D/A converter 22 is set to the active state. In the active state of the DLL circuit, the initialization unit 34 monitors the count value COUNT of the counter 20, and sets the reference voltage Vref by controlling the bias circuit 24 such that the amount of fluctuation in the count value COUNT is contained within a predetermined range.

Specifically, the initialization unit 34 may perform the following steps.

1A. An initial value COUNT_INIT is supplied to the counter 20.

1B. The bias voltage Vbias is adjusted by the feedback operation such that the delay amount of the sub-delay element 14 matches the period of the reference clock signal REFCLK, thus locking the DLL circuit.

1C. The initialization unit 34 monitors the count value COUNT of the counter 20 for a predetermined period of time. The reference voltage Vref is set so as to prevent overflow or underflow of the amount of fluctuation in the count value COUNT obtained as a result of the monitoring. The predetermined period of time is preferably set to be longer than the period of time required for locking the DLL circuit.

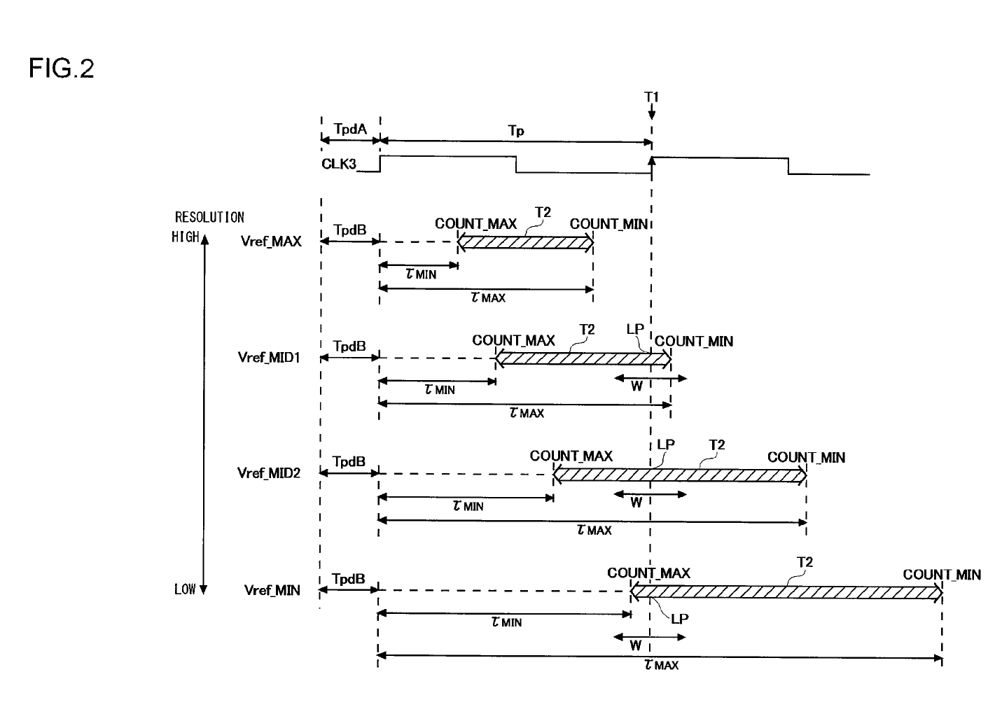

FIG. 2 shows diagrams showing the relation between the reference voltage Vref and the count value COUNT in the actual operation of the delay circuit 40 shown in FIG. 1. The horizontal axis in each diagram represents time. The top diagram shows the timing T1 of the edge after one cycle of the clock signal CLK3 at the node N3. The hatched regions in the second through fifth diagrams show the range of fluctuation in the edge timing T2 of the clock signal CLK2 at the node N2 when the reference voltage Vref is changed. The second diagram corresponds to a case in which the reference voltage is set to the maximum value Vref_MAX, and the fifth diagram corresponds to a case in which the reference voltage is set to the minimum value Vref_MIN. The third and fourth diagrams correspond to a case in which the reference voltage is set to an intermediate value Vref_MID1, and a case in which the reference voltage is set to another intermediate value Vref_MID2, respectively. It should be noted that the value of the reference voltage Vref is shown for exemplary purposes only. In practice, an arrangement may be made configured such that the reference voltage value can be set with further increased gradations of values. In the second diagram through the fifth diagram, the left end of the range of fluctuation of the timing T2 (COUNT_MAX) indicates the edge timing of the clock signal CLK2 when the count value of the counter 20 matches the maximum value. The right end (COUNT_MIN) indicates the edge timing of the clock signal CLK2 when the count value matches the minimum value.

The delay amount τ of the sub-delay element 14 is adjusted such that the edge timing T2 of the clock signal CLK2 at the node N2 matches the timing T1. Accordingly, there is a need to set the reference voltage Vref such that the range of fluctuation of the timing T2 includes the timing T1. In the example shown in FIG. 2, the reference voltage Vref_MAX cannot be used, and the reference voltages VREF_MID1 and VREF_MID2 can be used.

When the reference voltage Vref_MID1 is selected, the lock point LP of the count value is set in the vicinity of the minimum count value COUNT_MIN of the counter 20. On the other hand, when the reference voltage VrefMIN is selected, the lock point LP is set in the vicinity of the minimum value COUNT_MAX of the counter 20.

The tracking bandwidth W must be considered in the optimization of the reference voltage Vref. If the power supply voltage and the temperature are constant, the lock point LP is maintained at a constant value. However, in an actual operation state, the lock point LP fluctuates within a certain tracking bandwidth W due to fluctuation in the power supply voltage and fluctuation in the temperature. In a case in which the reference voltage Vref_MID1 or Vref_MIN is selected, the tracking bandwidth W is not covered. Accordingly, in this case, such an arrangement cannot operate such that the delay amount τ matches the target value Tp. In a case in which the reference voltage Vref_MID2 is selected, the entire tracking bandwidth W is covered. Thus, even in the case of fluctuation in the power supply voltage or fluctuation in the temperature, such an arrangement provides a stable delay mount τ.

By performing the first calibration operation, such an arrangement is capable of monitoring the fluctuation in the count value, i.e., the tracking bandwidth W in an actual operation of the DLL circuit. With such an arrangement, the reference voltage Vref is set such that the fluctuation in the count value is within a range between the minimum value and the maximum value of the counter, thereby providing a desired delay amount τ.

Furthermore, the initialization unit 34 may use the count value that corresponds to the lock point LP defined according to the reference voltage thus set as the initial value to be set for the counter 20. Such an arrangement provides the advantage of reducing the lock time required for the DLL circuit.

2. Second Calibration Operation.

The initialization unit 34 sets (or performs coarse adjustment of) at least one of either the reference voltage Vref or the initial value COUNT_INIT of the count value to be set for the counter 20, based upon the period of the loop oscillator 30 measured by the period measurement unit 32.

The second calibration operation is preferably employed in conjunction with the first calibration operation. In this case, the second calibration should be executed before the first calibration operation.

In the second calibration operation, specifically, the initialization unit 34 may perform the following steps.

2A. The first selector 12 selects the loop clock signal LOOPCLK, the second selector 26 selects the selected clock signal CLK3 that has propagated through the bypass path 16, and the counter 20 is fixed to a given initial value COUNT_INT. In this state, the first period Tpd1 of the loop oscillator 30 measured by the period measurement unit 32 is acquired.

2B. The first selector 12 selects the loop clock signal LOOPCLK, the second selector 26 selects the selected clock signal CLK2 that has propagated through the sub-delay element 14, and the counter 20 is fixed to the same initial value COUNT_INIT as that used in 2A. In this state, the second period Tpd2 of the loop oscillator 30, which is measured by the period measurement unit 32, is acquired.

2C. At least one of either the reference voltage Vref or the initial value COUNT_INT is set such that the difference ΔTpd (=Tpd2−Tpd1) between the second period Tpd2 and the first period Tpd1 is within a predetermined range. The predetermined range is a range with the period Tp of the reference clock signal REFCLK as its center.

For example, in a case in which the period Tp=4 ns, the predetermined range is between 3 ns and 5 ns. With reference to FIG. 1, TpdA′ represents the propagation time required for a signal to propagate through the bypass path 16 from the node N1 to the node N3′. The propagation time required for a signal to propagate through a path including the sub-delay element 14 from the node N1 to the node N2′ is represented by (TpdB′+τ). The symbol τ represents the delay amount of the sub-delay element 14, and TpdB′ represents the propagation time required for a signal to propagate through a line having no sub-delay element 14 that extends from the node N1 to the node N2′.

With TpdC as the propagation time required by a signal to propagate through a path from the output N4 of the second selector 26 to the node N1, the first period Tpd1 and the second period Tpd2 are represented by the following Expressions.

Tpd1=TpdA′+TpdC

Tpd2=TpdB′+τ+TpdC

Accordingly, in a circuit designed such that the relation TpdA′=TpdB′ is satisfied, the relation ΔTpd=Tpd2−Tpd1=τ is satisfied. Thus, by adjusting the reference voltage Vref and the initial value COUNT_INIT of the counter such that the difference time Tpd is positioned in the vicinity of the target value (Tp) of the delay time τ, or such that the difference time Tpd perfectly matches the target value Tp, such an arrangement provides a suitable calibration operation of the delay circuit 40.

3. Third Calibration Operation.

The initialization unit 34 calculates the resolution of the counter 20 based upon the period of the loop oscillator 30 measured by the period measurement unit 32, and sets (or performs coarse adjustment of) at least one of either the reference voltage Vref or the initial value COUNT_INIT of the count value of the counter 20.

This operation is preferably performed in conjunction with the first calibration operation. In this case, the third calibration operation should be executed before the first calibration operation.

Specifically, in the third calibration operation, the initialization unit 34 may perform the following steps.

3A. The first selector 12 selects the loop clock signal LOOPCLK, the second selector 26 selects the selected clock signal CLK3 that has propagated through the bypass path 16, and the counter 20 is fixed to a first count value (e.g., minimum value COUNT_MIN). In this state, the third period Tpd3 provided by the loop oscillator 30, which is measured by the period measurement unit 32, is acquired.

3B. The first selector 12 selects the loop clock signal LOOPCLK, the second selector 26 selects the selected clock signal CLK2 that has propagated through the sub-delay element 14, and the counter 20 is fixed to a second count value (e.g., maximum value COUNT_MAX). In this state, the fourth period Tpd4 provided by the loop oscillator 30, which is measured by the period measurement unit 32, is acquired.

3C. The difference ΔTpd (=Tpd3−Tpd4) between the third period Tpd3 and the fourth period Tpd4 is divided by the difference between the first count value (COUNT_MIN) and the second count value (COUNT_MAX). Thus, the resolution Δτ can be calculated.

Δτ=(Tpd3−Tpd4)/(COUNT_MAX−COUNT_MIN)

4C. The initialization unit 34 sets the reference voltage Vref such that the resolution Δτ thus calculated is within a predetermined range.

The resolution Δτ that can be obtained by the third calibration operation can be used as a parameter to set the loop gain of the DLL circuit. Thus, such an operation provides optimized loop gain.

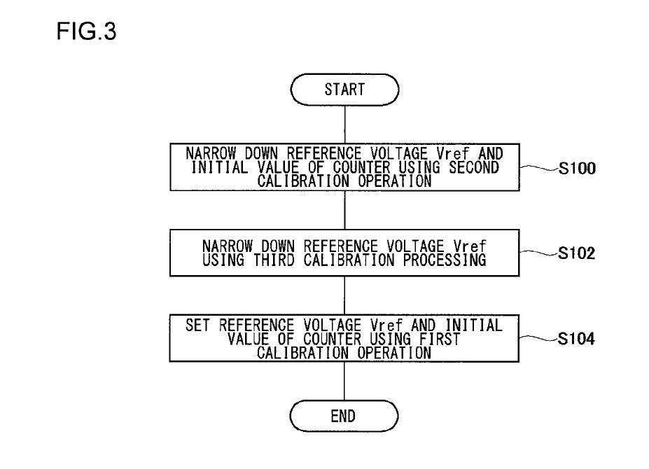

FIG. 3 is a flowchart which shows a calibration operation obtained by combining the first through third calibration operations. In the flowchart shown in FIG. 3, the second calibration operation 5100 and the third calibration operation 5102 are executed before the first calibration operation 5104. The order of the operations 5100 and 5102 may be rearranged, and also only one desired calibration operation may be executed. Also, the order of the calibration operations 5100 through 5104 may be rearranged.

Next, description will be made regarding the reason why the first calibration operation must be performed.

In a case in which the number of bits of the counter 20 is sufficiently large, there is no need to perform the first calibration operation. However, such an arrangement has a disadvantage in that the circuit scale of the counter 20 is increased.

Also, in a case in which the tracking bandwidth of the counter 20 that is required to maintain the delay amount τ at a constant level is sufficiently narrow, there is no need to perform the first calibration operation. It should be noted that, in this case, fluctuation in the device characteristics due to fluctuation in the temperature or fluctuation in the power supply voltage must be small. Accordingly, such a counter circuit might require an expensive semiconductor process.

The point in common between the second and third calibration operations is that the loop oscillator 30 is used. In a case in which the delay amount (TpdB′+τ) of the path from the node N1 to the node N2′ in the loop oscillator 30 is equal to the delay amount (TpdB+τ) from the node N1 to the node N2 in the DLL circuit, and the delay amount TpdA′ of the path from the node N1 to the node N3′ is equal to the delay amount TpdA of the path from the node N1 to the node N3 in the DLL circuit, the initial value of the counter 20 set as a result of the second and third calibration operations will approximately match the lock point of the DLL circuit. In this case, there is no need to perform the first calibration operation.

However, in a case in which TpdB is not the same as TpdB′, in a case in which TpdA is not the same as TpdA′, or in a case in which the propagation delay applied to the clock signal CLK2 in the internal circuit of the second selector 26 differs from that of the clock signal CLK3, a significant deviation could occur between the initial value COUNT_INIT set for the counter 20 and the lock point of the DLL circuit in the actual operation even after the delay circuit 40 is initialized by means of the second and third calibration operations using the loop oscillator 30. In this case, there is a possibility that such an arrangement cannot cover the tracking bandwidth required by the DLL circuit.

In a case in which the first calibration operation is performed, such an arrangement adjusts the reference voltage Vref in the actual operation of the DLL circuit so as to ensure a sufficient tracking margin. Thus, such an arrangement provides a stable delay amount τ in a sure manner even if there is a difference between the initial value COUNT_INIT set for the counter 20 and the lock point LP of the DLL circuit.

Next, description will be made regarding a suitable application of the delay circuit 40.

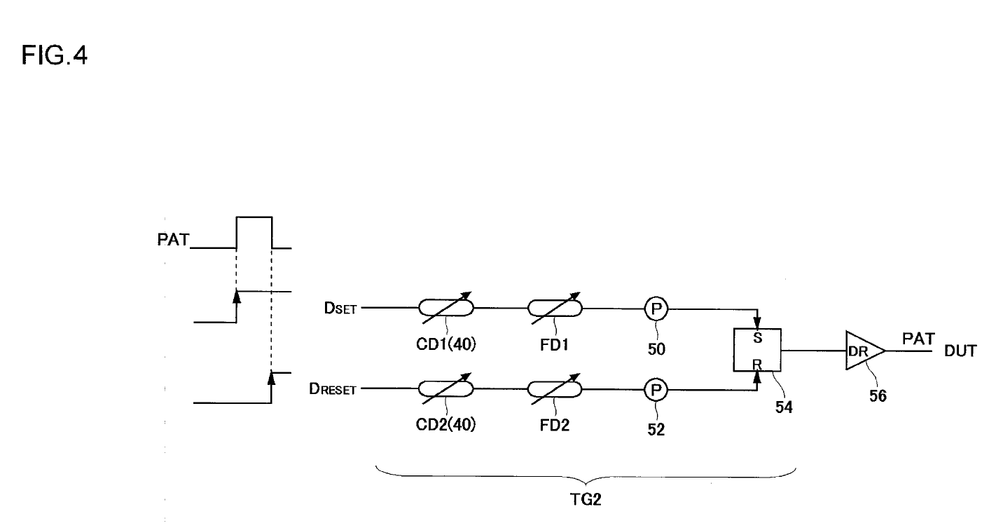

FIG. 4 is a block diagram which shows a configuration of a timing generator (TG) 2 employing the delay circuit 40 shown in FIG. 1 and a test apparatus 100. The test apparatus 100 has a typical configuration including the timing generator 2, a pattern generator PG (not shown), and a waveform shaper FC (not shown).

The unshown pattern generator PG generates a signal D_{SET} to be used to set a positive edge timing of a test pattern and a signal D_{RESET} to be used to set a negative edge timing thereof. The signal D_{SET} is generated when the test pattern is to be switched from low level to high level, and the signal D_{RESET} is generated when the test pattern is to be switched from high level to low level.

The timing generator 2 applies a predetermined delay to each of the signals D_{SET} and D_{RESET} to be used to set the edge timings of the test pattern. The timing generator 2 includes a first delay circuit CD1, a second delay circuit CD2, a third delay circuit FD1, a fourth delay circuit FD2, pulsers 50 and 52, and an RS flip-flop 54.

The first delay circuit CD1, the third delay circuit FD1, and the pulser 50 are connected in series. The first delay circuit CD1 applies a coarse delay to the signal D_{SET}, and the third delay circuit FD1 applies a fine delay to the signal D_{SET}. The second delay circuit CD2 applies a coarse delay to the signal D_{RESET}, and the fourth delay circuit FD2 applies a fine delay to the signal D_{RESET}.

The signals D_{SET} and D_{RESET} thus delayed are each converted into a pulse by means of the pulsers 50 and 52, and the respective pulse signals thus converted are input to the set terminal and the reset terminal of the RS flip-flop 54. The output signal of the RS flip-flop 54 is supplied to a DUT via a driver 56.

In such a timing generator 2, the delay circuit shown in FIG. 1 can be suitably employed as the first delay circuit CD1 and the second delay circuit CD2.

Description has been made regarding the present invention with reference to the embodiment. The above-described embodiment has been described for exemplary purposes only, and is by no means intended to be interpreted restrictively. Rather, it can be readily conceived by those skilled in this art that various modifications may be made by making various combinations of the aforementioned components or processes, which are also encompassed in the technical scope of the present invention. Description will be made below regarding such a modification.

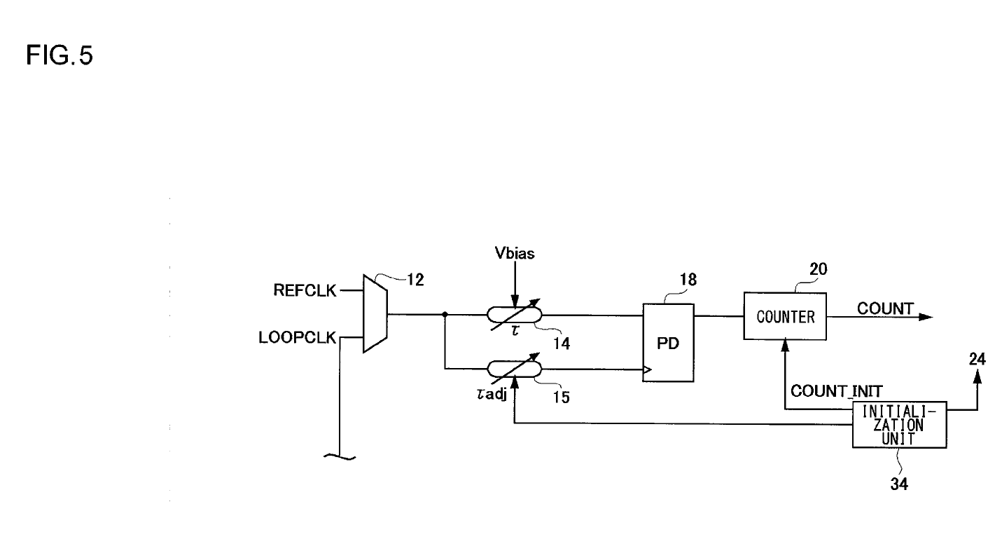

FIG. 5 is a circuit diagram which shows a configuration of a delay circuit 40a according to a modification. A portion including the same components as those shown in FIG. 1 is not shown. The delay circuit 40a further includes a delay element 15 used to perform skew adjustment, in addition to the configuration of the delay circuit 40 shown in FIG. 1. The delay element 15 applies a fixed delay to the selected clock signal CLK1, independent of the bias voltage Vbias.

Such an arrangement provides the following calibration operation.

1. The count value of the counter 20 is set in the vicinity of the midpoint of the counter range.

2. The initialization unit 34 sets the reference voltage Vref and the delay amount τadj of the delay element 15 such that the difference between the propagation delay of the sub-delay element 14 and the propagation delay of the bypass path 16 is equal to a target value Tp.

By performing such an operation, such an arrangement is capable of setting the lock point LP in the vicinity of the center of the range of the counter 20, thereby allowing the tracking margin to be easily ensured.

The delay element 15 and the sub-delay element 14 may be arranged in series.

Description has been made regarding the present invention with reference to the embodiments. However, the above-described embodiments show only the mechanisms and applications of the present invention for exemplary purposes only, and are by no means intended to be interpreted restrictively. Rather, various modifications and various changes in the layout can be made without departing from the spirit and scope of the present invention defined in appended claims.

What is claimed is:

1. A delay circuit configured to apply a delay to an input signal, the delay circuit comprising:
a main delay element configured to apply a delay that corresponds to a bias voltage to the input signal;
a first selector configured to receive a reference clock signal and a loop clock signal, and to select one signal from among these two signals thus received;
a sub-delay element having the same configuration as that of the main delay element, and configured to apply a delay that corresponds to the bias voltage to a selected clock signal output from the first selector;
a bypass path configured to bypass the sub-delay element;
a phase detector configured to detect the phase difference between the selected clock signal that has propagated through the sub-delay element and the selected clock signal that has propagated through the bypass path, and to generate a phase detection signal having a level that corresponds to the phase difference thus detected;
a counter configured to perform a counting operation according to the level of the phase detection signal received from the phase detector;
a D/A converter configured to convert the count value of the counter into an analog voltage, and to supply the analog voltage thus converted as the bias voltage to the main delay element and the sub-delay element;
a bias circuit configured to generate a reference voltage to be supplied to the D/A converter; and
a loop oscillator comprising a second selector configured to receive the selected clock signal that has propagated through the sub-delay element and the selected clock signal that has propagated through the bypass path, to select one from among the clock signals thus received, and to supply the clock signal thus selected as the loop clock signal to the first selector, and configured to operate as an oscillator in a state in which the first selector selects the loop clock signal.

2. A delay circuit according to claim 1, further comprising an initialization unit configured to instruct the delay circuit to operate, to monitor the count value of the counter, and to set the reference voltage such that fluctuation in the count value is within a predetermined range, in a state in which the first selector selects the reference clock signal.

3. A delay circuit according to claim 2, wherein, in the calibration operation, the initialization unit instructs the delay circuit to operate for a predetermined period of time in a state in which the first selector selects the reference clock signal, and sets the reference voltage so as to prevent overflow or underflow of the count value of the counter.

4. A delay circuit according to claim 2, further comprising a period measurement unit configured to measure a period of the loop oscillator,
wherein the initialization unit sets at least one from among the reference voltage and the initial value of the counter based upon the period measured by the period measurement unit.

5. A delay circuit according to claim 4, wherein the initialization unit performs coarse adjustment of at least one from among the reference voltage and the initial value of the counter, based upon the period before the setting of the reference voltage based upon the fluctuation in the count value.

6. A delay circuit according to claim 4, wherein the first initialization unit acquires a first period of the loop oscillator, measured by the period measurement unit in a state in which the first selector selects the loop clock signal, the second selector selects the selected clock signal that has propagated through the bypass path, and the counter is fixed to an initial value,
and wherein the initialization unit acquires a second period of the loop oscillator, measured by the period measurement unit in a state in which the first selector selects the loop clock signal, the second selector selects the selected clock signal that has propagated through the sub-delay element, and the counter is fixed to the initial value,
and wherein the initialization unit sets at least one from among the reference voltage and the initial value such that the difference between the second period and the first period is within a predetermined range.

7. A delay circuit according to claim 6, wherein the predetermined range includes a period of the reference clock signal.

8. A delay circuit according to claim 4, wherein the initialization unit acquires a third period of the loop oscillator measured by the period measurement unit in a state in which the first selector selects the loop clock signal, the second selector selects the selected clock signal that has propagated through the sub-delay element, and the counter is fixed to a first count value,
and wherein the initialization unit acquires a fourth period of the loop oscillator measured by the period measurement unit in a state in which the first selector selects the loop clock signal, the second selector selects the selected clock signal that has propagated through the sub-delay element, and the counter is fixed to a second count value,
and wherein the initialization unit acquires a resolution by dividing the difference between the third period and the fourth period by the difference between the first count value and the second count value,
and wherein the initialization unit sets the reference voltage such that the resolution thus acquired is within a predetermined range.

9. A delay circuit according to claim 8, wherein the initialization unit performs coarse adjustment of the reference voltage based upon the resolution before the reference voltage is set according to the fluctuation in the count value.

10. A timing generator to be mounted on a test apparatus configured to supply a test pattern to a device under test, the timing generator comprising a delay circuit according to claim 1, configured to apply a predetermined delay to a signal used to set an edge timing of the test pattern.

11. A test apparatus configured to supply a test pattern to a device under test, the test apparatus comprising:
a pattern generator configured to generate a test pattern; and
generator according to claim 10, configured to be capable of changing the edge timing of the test pattern as desired.
